(19) United States
(12) Patent Application Publication
(10) Pub. No.: US 2012/0080607 A1
(43) Pub. Date: Apr. 5, 2012

(54) RADIATION DETECTOR WITH INTEGRATED READOUT

(76) Inventor: Karim Sallaudin Karim, Waterloo (CA)

(21) Appl. No.: 13/315,793

(22) Filed: Dec. 9, 2011

(30) Foreign Application Priority Data
Jun. 14, 2010 (CA) PCT/CA2010/000890

(51) Int. Cl. G01T 1/24; H01L 31/18; H01L 31/02; G01T 1/16

(52) U.S. Cl. 250/370.13; 250/336.1; 250/370.01; 250/370.12; 438/88; 250/214.1; 257/E31.111

(57) ABSTRACT

The disclosure is directed at a radiation detector comprising a substrate layer of detector material; a set of readout electronics deposited and integrated on one side of the substrate layer; and a contact layer deposited on a side of the substrate layer opposite the set of readout electronics.

### FIELD OF THE DISCLOSURE

The disclosure is generally directed at X-ray or gamma-ray detectors and more specifically at a radiation detector with integrated readout.

### BACKGROUND OF THE DISCLOSURE

The use of X-ray detectors is well known in which they are typically used in the medical field to assist in diagnosing or identifying bone structures, lung diseases, intestinal obstructions or to detect the pathology of an individual.

Current X-ray detector technology includes an X-ray detector which uses silicon as a substrate layer within which a Metal Oxide Semiconductor Field Effect Transistor (MOSFET) is grown or the use of a glass substrate atop which a thin film transistor (TFT) can be placed, however each of these examples suffer from some problems.

For instance, with an X-ray detector in which the MOSFET is grown within the silicon bulk, associated problems include but are not limited to the requirement of complex processes to fabricate and operate, high costs or low yield particularly in a large area format. With an X-ray detector in which the TFT is simply deposited on top of a glass substrate, this type of detector is not capable of directly detecting X-rays and requires a discrete detector and a discrete readout.

Therefore, there is an improved radiation detector which overcomes at least some of the disadvantages of the prior art.

### SUMMARY OF THE DISCLOSURE

The disclosure is directed in one embodiment at an integrated detector and readout in a single chip to achieve direct X-ray detection which provides at least an advantage in cost-effectiveness and simplicity in readout electronics.

In one aspect, there is provided a radiation detector comprising a substrate layer of detector material; a thin film transistor (TFT) deposited on one side of the substrate layer; and a contact layer deposited on a side of the substrate layer opposite the TFT.

In another aspect, there is provided a method of manufacturing a radiation detector comprising depositing a substrate layer of detector material; depositing a thin film transistor (TFT) on one side of the substrate layer; and depositing a contact layer on a side of the substrate layer opposite the TFT.

### BRIEF DESCRIPTION OF THE DRAWINGS

Embodiments of the present invention will now be described, by way of example only, with reference to the attached Figures, wherein:

FIG. 1a is a schematic diagram of a radiation detector with integrated thin film transistor (TFT) as a readout;

FIG. 1b is a schematic diagram of potential distribution within the radiation detector of FIG. 1a;

FIG. 2 is a flowchart outlining a method of manufacturing a radiation detector with integrated TFT as readout;

FIG. 3 is a schematic diagram of a circuit model of the radiation detector of FIG. 1a;

FIG. 4 is a graph showing a Current-Voltage (I-V) curve of a detector;

FIG. 5 is graph showing a long transient dark current under different bias voltages;

FIGS. 6 and 7 are graphs showing transfer and output characteristics of the readout TFT;

FIGS. 8 and 9 are graphs showing display transfer and output characteristics of the readout TFT;

FIG. 10 is a schematic diagram of another embodiment of a radiation detector in accordance with the disclosure;

FIG. 11 is a schematic diagram of another embodiment of a radiation detector in accordance with the disclosure;

FIG. 12 is a schematic diagram of another embodiment of a radiation detector in accordance with the disclosure;

FIG. 13 is a flowchart outlining a method of manufacturing a radiation detector;

FIG. 14a is a schematic diagram of an active pixel sensor array;

FIG. 14b is a timing diagram for the active pixel sensor array of FIG. 14a;

FIG. 15a is a schematic diagram of a passive pixel sensor array;

FIG. 15b is a timing diagram for the passive sensor array of FIG. 15a; and

FIG. 16 is a schematic diagram of another embodiment of a radiation detector in accordance with the disclosure.

### DETAILED DESCRIPTION

The disclosure is directed at a radiation, such as an X-ray detector which, in one embodiment, includes the integration of a set of readout electronics with a bulk silicon X-ray detector in a single silicon wafer. In one embodiment, the set of readout electronics is a thin film transistor (TFT). As the TFT may be used as the readout electronics for the device, the X-ray detector of the current disclosure unites the readout portion with the detection, or bulk silicon diode, portion of the detector. As such, the novel radiation detector, in one embodiment, may be designated as a silicon X-ray detector with integrated TFT as readout. As will be understood, other detector materials may be used and will be discussed below.

In use, the detector is sensitive to X-ray exposure and may be used for various applications such as, but not limited to, protein crystallography, X-ray spectroscopy, micro-computed tomography (CT) and dosimetry.

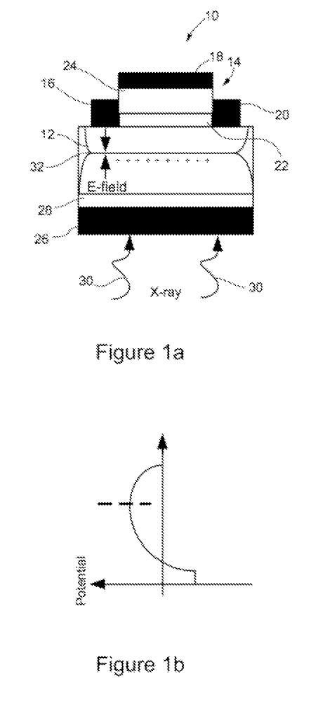

Turning to FIG. 1a, a schematic diagram of a radiation detector with integrated thin film transistor (TFT) as a readout is shown. In this embodiment, the radiation detector is a silicon X-ray detector. FIG. 1b is a schematic diagram of potential distribution within the detector of FIG. 1a.

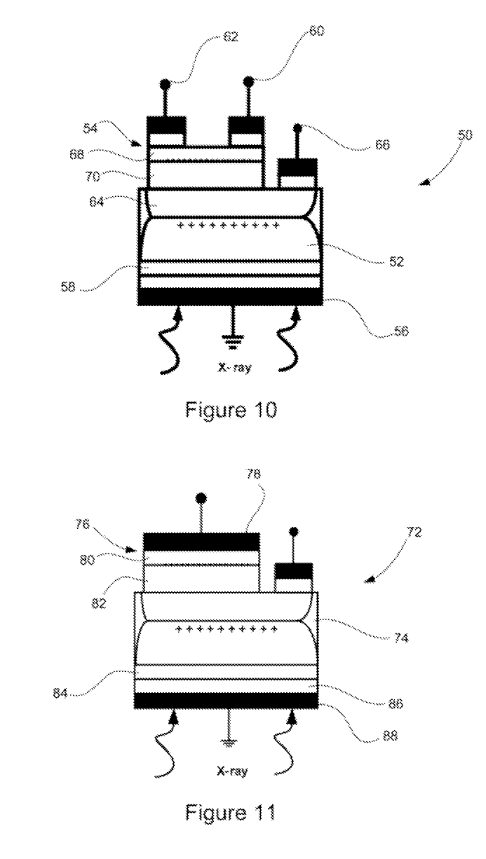

In the preferred embodiment, the detector 10 includes a substrate or detector layer 12 which is preferably made of a detector material such as, but not limited to, silicon (Si), indium phosphide (InP), gallium arsenide (GaAs), cadmium telluride (CdTe), cadmium zinc telluride (CdZnTe or CZT), lead oxide (PbO), mercury iodide (HgI), lead iodide (PbI) or the like. The detector 10 further includes a TFT 14 which is deposited on top of the substrate layer 12. The TFT 14 includes a source portion 16, a gate portion 18 and a drain portion 20, each of these portions 16, 18 and 20 being made of a metal, such as aluminum, so that the TFT 14 can serve as an electrode for the detector 10. As will be understood, the drain portion 20 and the source portion 16 can be reversed as well. The TFT 14 further includes a channel portion 22, preferably amorphous silicon and an insulating or dielectric layer 24, preferably silicon nitride (SiNₓ). In the embodiment of FIG. 1, the TFT 14 is a top gate TFT, however, a bottom gate TFT(as shown in FIG. 10) or a simple capacitive device may also be used.

If the substrate layer 12 is a p-doped substrate layer, then the TFT 14 is a n-type TFT and if the substrate layer 12 is a n-doped substrate layer, then the TFT 14 is a p-type TFT to create a Schottky contact.

Beneath the substrate layer 12 is a contact, or conductive metal layer, 26, such as aluminum, which serves as a second electrode for the detector 10. As shown in the current embodiment, a non-mandatory semiconductor layer 28 is sandwiched between the substrate layer 12 and the conductive metal layer 26. If the conductive metal layer 26 is made from aluminum, a further n-doped layer is sandwiched between the semiconductor layer 28 and the conductive metal layer 26. In one embodiment, the semiconductor layer is manufactured from hydrogenated amorphous silicon or a similar material having like properties.

The combination of the substrate and contact layers may be seen as a bottom bulk silicon diode, which is intended to directly detect X-rays. It may also be seen as a PN or PIN structure. In this case, the silicon, or substrate layer, acts as P and the amorphous silicon in the channel is I or N. Along with an N-type top contact in the TFT, as illustrated in FIG. 1a, the diode is similar to an N-P-I-N type. Since the substrate layer 12 may be slightly doped with very low free carrier concentration, a wide depletion region may be created which extends inside the bulk silicon or substrate layer 12. Current-voltage characteristics (I-V) and dark current are among important performance parameters for the detector and will be discussed below.

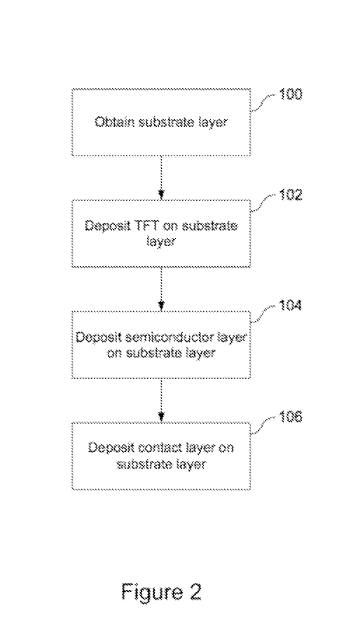

Turning to FIG. 2, a flowchart outlining a method of manufacturing a radiation detector with integrated TFT as readout is shown. Firstly, a detector material is obtained 100 to be used as the substrate layer. As disclosed above, the detector material is preferably silicon but can also be any other detector material having similar properties. A TFT is then deposited 102 on one side of the substrate layer, such as the top surface. A semiconductor layer, such as a Schottky layer, is then deposited 104 on a surface of the substrate layer opposite the TFT. As will be understood, this is an optional step since the semiconductor layer may not be required or desired. A contact layer is then deposited 106 on the semiconductor layer (or the substrate layer in the absence of the semiconductor layer). Depending on the material which is used for the contact layer, an n-doped layer may also be deposited between the contact layer and the semiconductor layer of the contact layer and the substrate layer.

In operation, a bias is applied to the TFT and the contact layer in order to create an electrical field within the substrate layer. As will be understood, the bias is applied when the detector is in operation and the application of the bias is not performed during the manufacturing stage, however, the components for preparing the TFT and contact layers for receiving the bias may be integrated during the manufacturing process.

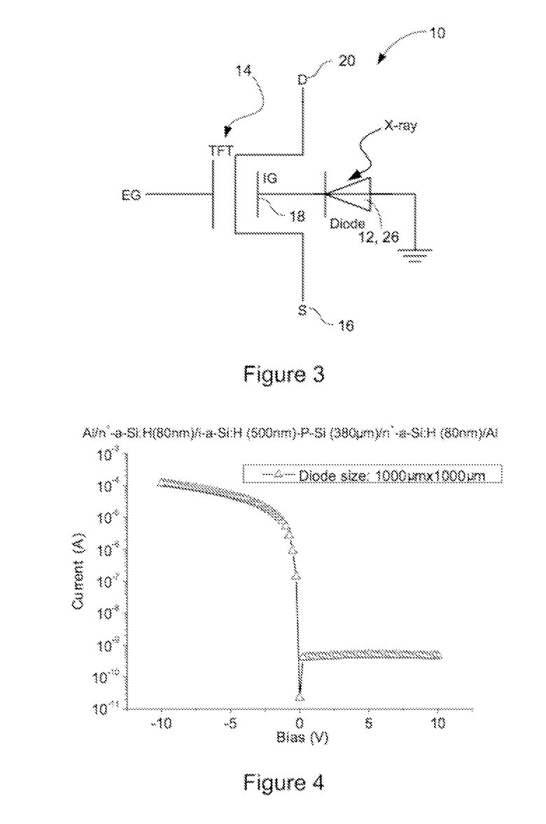

FIG. 3 is a schematic diagram of a circuit model of the radiation detector of FIG. 1a. Schematically, the schematically 10 includes the TFT 12 which has its gate portion 18 connected to a diode portion (the substrate and contact layers) which is connected to ground.

Turning back to FIG. 1a, in use, after bias voltages are applied to the TFT 14 and the conductive metal layer 26, an electric field is created within the substrate layer 12. As X-ray photons are transmitted into the detector such as in the direction shown by arrows 30, electron-hole pairs are created within the substrate layer 12 due to the electric field created by the bias voltages.

In one example, the positive charges (or the holes), collect at a mid-point 32 of the substrate layer 12 while the negative charges, or electrons, collect at either the TFT 14, in the channel area 22, or the conductive metal layer 26. In other words, the positive charges accumulate and locate at a border where the field strength of the electric field is strongest. These positive charges induce negative charges inside the channel layer 22 of the TFT 14 to control its output characteristics. The charges collected at the TFT 14 assist in determining the image as it is also functioning as the readout electronics. As can be see in the following equation, the drain current changes in response to X-ray exposure when the detector is in operation.

The drain current (Ids) of a TFT is typically governed by the following equation:

$${I}_{{D}_{S}} = \frac{W {μ}_{F} {C}_{i}}{{L}^{E}} {[}_{(} {V}_{{G}_{S}} - {V}_{T} ) {V}_{{D}_{S}} - \frac{1}{2} {V}_{{D}_{S}}^{2} ]$$

where V_{DS}<(V_{GS}−V_{T}), where W and L represent the channel width and length, respectively, Cᵢ is the capacitance of the gate dielectric (SiNₓ) per unit area, μ_{FE} is the field-effect mobility of the TFT and V_{DS}, V_{GS} and V_{T} are the gate bias voltage, threshold voltage and drain-source bias respectively.

The X-ray induced internal gate bias is given by

$${V}_{IG} = \frac{{Q}_{x}}{{C}_{D}} where {Q}_{x} = \frac{{qE}_{x} ηφ}{{W}_{\pm }} , {C}_{D} = \frac{{ɛ}_{Si}}{{t}_{Si}}$$

where the induced charge Q_{X} is a function of the X-ray photon energy E_{X}), an absorption coefficient η, X-ray photon flux φ and electron-pair creation energy W_{±} which is 3.6 eV for silicon.

Assuming here bulk silicon is completely depleted, the junction capacitance is denoted as C_{D}, which is proportional to the thickness of silicon, t_{Si}. ε_{Si} is the dielectric constant of silicon, which is 12. The increased drain current due to X-ray exposure, is therefore associated with V_{IG}:

Therefore

$$Δ {I}_{DS} = \frac{W {μ}_{FE} {C}_{i}}{L} {V}_{IG} {V}_{DS} where {V}_{DS} < ( {V}_{GS} - {V}_{T} )$$

The change in the drain current helps to confirm that that the silicon photodiode at the bottom is operational since a rectification behavior is observed.

Turning to FIG. 4, an I-V curve which was observed with a silicon X-ray detector in accordance with the disclosure is shown. The diode, or substrate layer, was biased between the TFT and the contact layer and the layer 25 was designated as common ground. The diode size was defined around 1000 μm×1000 μm in this sample detector. As can be seen in FIG. 4, the sample detector exhibited an excellent diode behavior with a rectification current ratio of 10⁶ and a low reverse current of approximately 10⁻¹⁰ A at a bias of 10 V. The reverse bias current (dark current) corresponds to signal to noise ratio of the detector. Prior art silicon-based detectors require cryogenic or thermoelectric cooling in order to reduce dark current as well as noise level, however, in the current embodiment the dark current is low enough to be useable at room temperature without cooling.

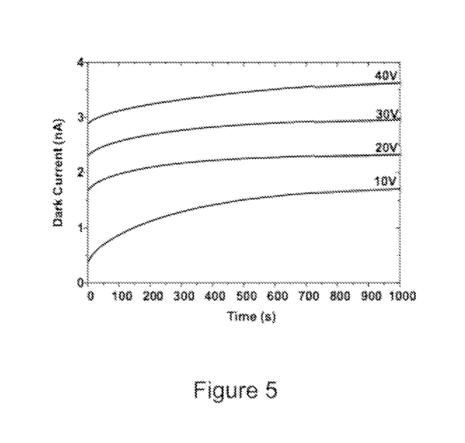

Turning to FIG. 5, a chart outlining a dark current under different bias voltages is shown. The dark current is reasonably stable and remains at a low level (below 10 nA) over 1000s. The slight increase in the dark current with respect to time and bias voltages may be related to charge releasing from amorphous silicon layers.

With respect to the TFT operating as the readout electronics, or as a readout unit, in one embodiment, the TFT is configured to be a top gate staggered structure and the drain current of TFT is tuned by both the external and internal gates.

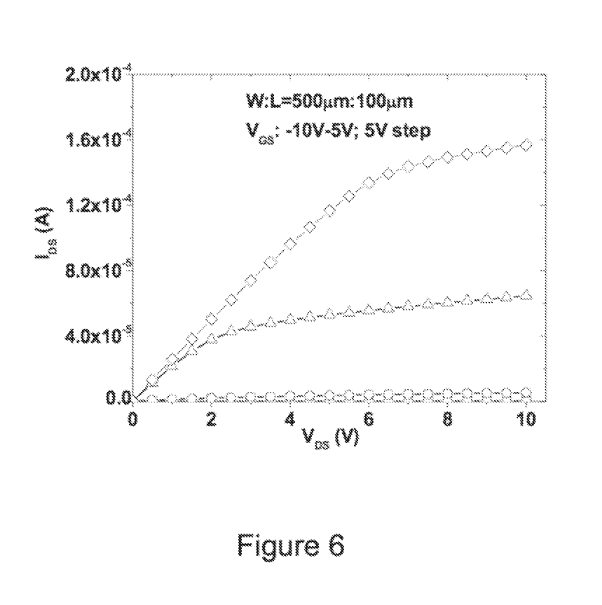

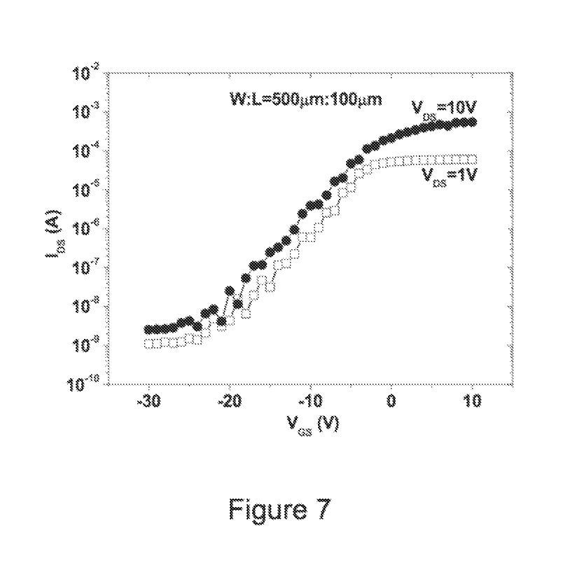

The external gate is biased at a set voltage and the internal gate is induced by X-ray generated charges from the bulk silicon as disclosed above. FIGS. 6 and 7 show transfer and output characteristics of the readout TFT. The TFT works as a field-effect device with ON/OFF ratio of approximately 10⁴ and low OFF current of 10⁻⁹ A at a bias of −30 V in this particular case. Both the TFT and silicon diode work independently and can be controlled by properly designing processes, such that the TFT can be built on top of silicon wafers. By building on top of silicon wafers, many other detector applications may be contemplated.

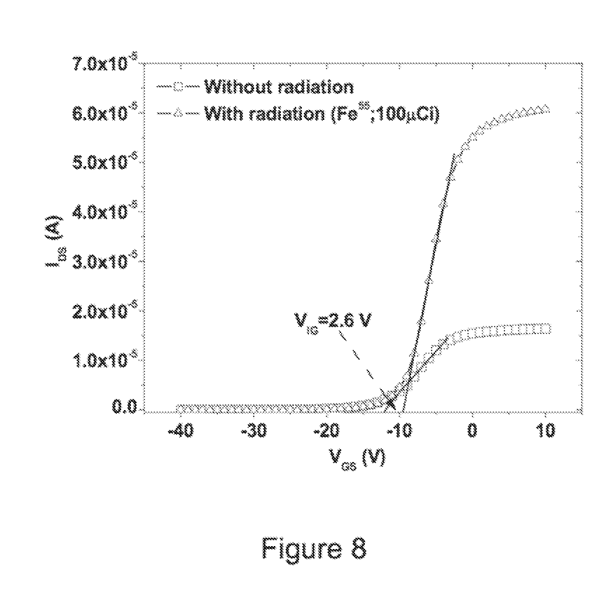

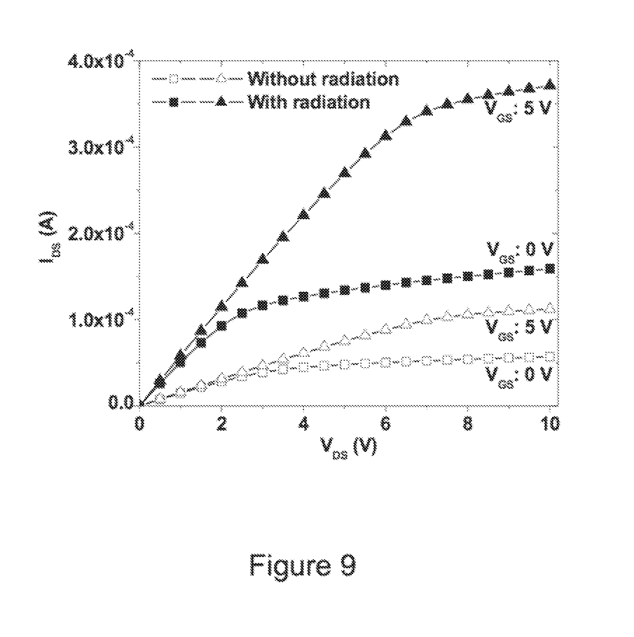

Finally, with respect to the response of the example detector to X-ray radiation, in order to demonstrate the X-ray capability, the TFT characteristics under X-ray exposure were evaluated in terms of transfer and output characteristics. FIGS. 8 and 9 display transfer and output characteristics of the readout TFT (W:L=1000 μm:1000 82 m) in response to X-ray radiation, respectively. As can be seen, the drain current increases when the device receives the X-ray photons. The X-ray radiation was generated by a potable nuclear source of 100 μCi Fe⁵⁵ with photon energy of around 6 KeV and dose of around 5 mR. From the comparison of the two transfer characteristics with and without radiation, the internal gate induced by the X-ray exposure can be extracted and the value is around 2.6 V.

Turning to FIG. 10, a schematic diagram of another embodiment of a radiation detector with integrated TFT as readout is provided. As shown, the radiation detector 50 includes a layer of detector material 52 which represents a substrate layer. In this embodiment, the TFT is a bottom gate TFT 54 and is deposited on one side of the substrate layer of detector material 52 and a contact layer 56 is deposited on the detector layer 52 on a side opposite the TFT 54. As will be understood, the contact layer is preferably a metal such as aluminum or the like. In some embodiments, a semiconductor layer 58 may be deposited between the contact layer 56 and the substrate layer 52. As shown, the contact layer 56 is connected to ground while the TFT is biased in order to create the electric field within the substrate layer during the image detecting process. Alternatively, both the TFT and the contact layer may be biased to create the requisite electric field.

The TFT 54 includes a source portion 60, a drain portion 62 and a gate portion 64 (generally located within the substrate layer 52). The TFT 54 further includes a reset portion 66 along with a channel portion 68, preferably amorphous silicon and an insulating or dielectric layer 70, preferably silicon nitride (SiNₓ).

Turning to FIG. 11, a schematic diagram of another embodiment of a radiation detector with integrated readout. In this embodiment, a Metal-Insulator-Semiconductor (MIS) structure is used. The radiation detector 72 includes a layer of detector material, or substrate layer, 74 atop which a MIS 76 is deposited. The MIS structure 76 includes a metal layer 78, an insulator layer 80 and a semiconductor layer 82. On the other side of the detector layer 74 is a semiconductor layer 84, an n-doped silicon layer 86 to reduce the contact resistance between the semiconductor layer 84 and a contact layer 88, preferably aluminum or the like.

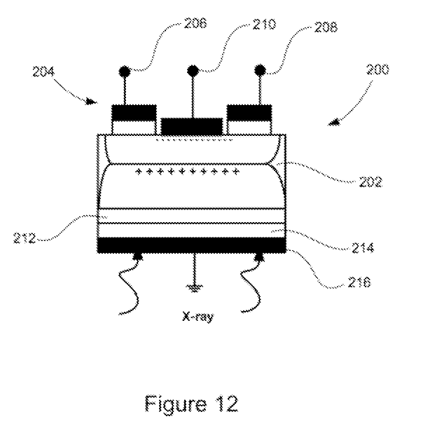

Turning to FIG. 12, a schematic diagram of yet a further embodiment of a radiation detector with integrated readout is shown. In this embodiment, a Metal-Semiconductor (MES) TFT is used. The radiation detector 200 includes a layer of detector materialor substrate layer 202 atop which a MES TFT 204 is deposited. The MES TFT 204 includes a drain portion 206, a source portion 208 and a gate portion 210. On the other side of the detector layer 202 is a semiconductor layer 212 and an n-doped silicon layer 214 to reduce the contact resistance between the semiconductor layer 212 and a contact layer 216.

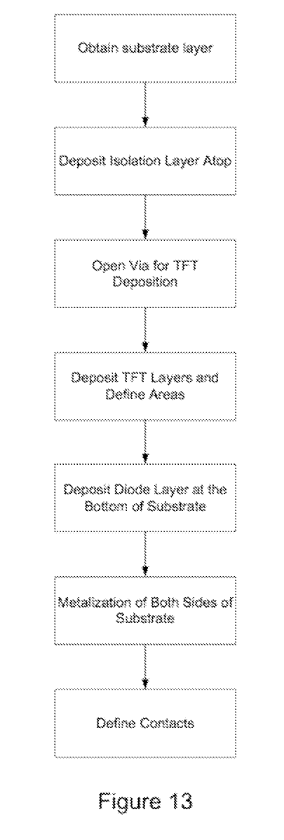

Turning to FIG. 13, a flowchart outlining another method of manufacturing a radiation detector with an integrated readout is shown. In this embodiment, a substrate layer is obtained 200 whereby the substrate layer is a detector material such as silicon or the like. Other examples of detector material are listed above. An isolation layer is then deposited 202 on top of the substrate layer. A via is then opened 206 for readout electronics, such as TFT, deposition. The TFT is then deposited 208 and specific areas defined such as the drain, the source and the gate. In an alternative embodiment, the deposition may be contact areas or a contact area for a reset electrode. A diode layer is then deposited 210 on a bottom side of the substrate layer. Both sides of the substrate are then metalized 212 and contacts are then defined 214 on both sides of the substrate layer.

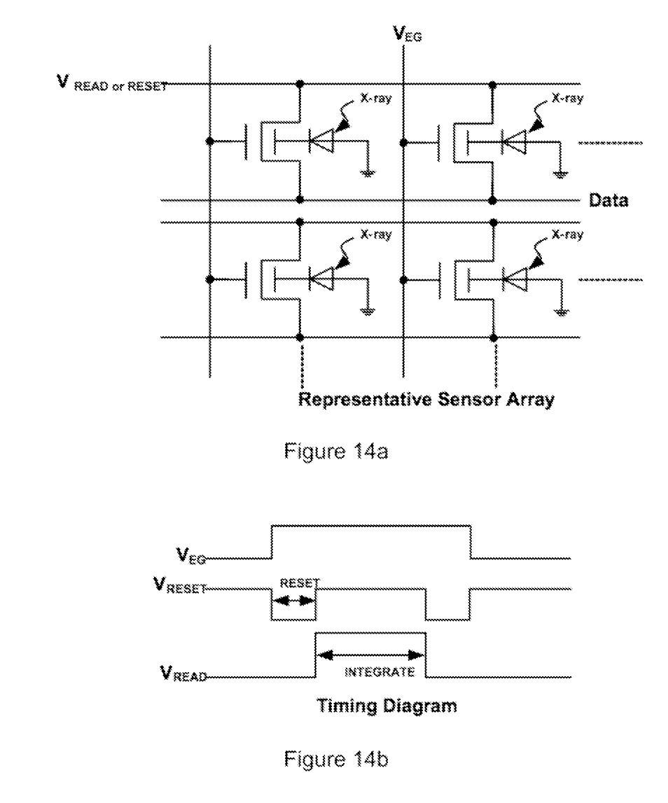

Turning to FIG. 14a, a circuit diagram of a one transistor, or TFT, active pixel sensor array is shown and in FIG. 14b, a timing diagram for the sensor array of FIG. 14a is shown. In operation, the voltage V_{EG} which is the external gate voltage, goes high and turns on the TFT. The silicon diode (combination of substrate layer and contact layer), is reset and then enters an integration mode. The RESET and READ nodes both connect to the drain portion of the TFT so that when a signal is read by the readout electronics, integration is simultaneously started. For TFT configuration, the Read and Reset nodes are realized by biasing drain and source in a timely fashion. After the integration process, the RESET portion is pulsed to remove all stored charges in the diode.

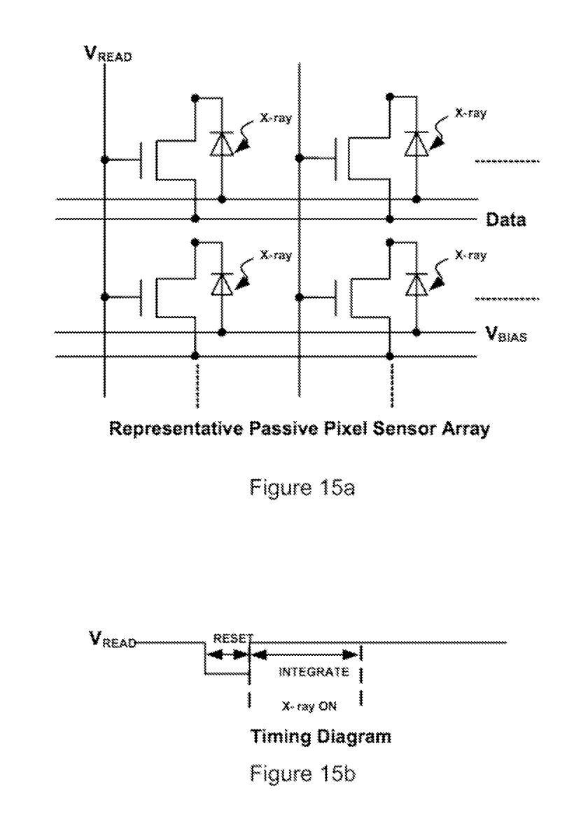

Turning to FIG. 15a, a circuit diagram of a passive sensor array is shown and in FIG. 15b, a timing diagram for the passive sensor array of FIG. 15a is shown. In this embodiment, the drain portion of the TFT is connected with the diode portion. In the RESET mode, the diode is reverse gated and therefore removes the charges which are stored and awaits integration. When X-ray imaging is being used, the TFT is placed in READ mode by positively biasing the gate.

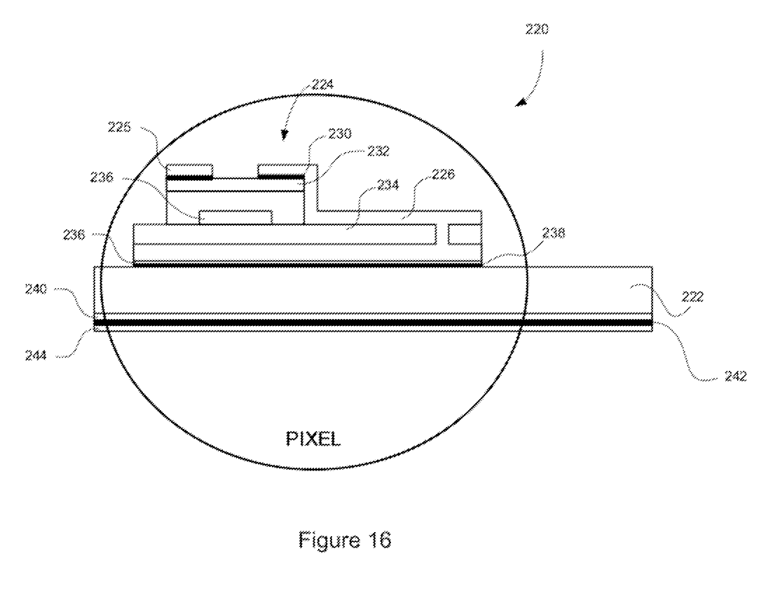

Turning to FIG. 16, another schematic diagram of a radiation detector with integrated readout electronics is shown. In this embodiment, the detector layer operates as a conventional photodiode. The detector 220 includes a substrate layer of detector material 222 with a TFT 224 deposited and integrated on one side of the detector layer 222. The bottom gate TFT 224 includes a source portion, a drain portion and a gate portion.

In the preceding description, for purposes of explanation, numerous details are set forth in order to provide a thorough understanding of the embodiments of the disclosure. However, it will be apparent to one skilled in the art that some or all of these specific details may not be required in order to practice the disclosure. In other instances, well-known electrical structures and circuits are shown in block diagram form in order not to obscure the disclosure. For example, specific details are not provided as to whether the embodiments of the disclosure described herein are as a software routine, hardware circuit, firmware, or a combination thereof.

The above-described embodiments of the disclosure are intended to be examples only. Alterations, modifications and variations can be effected to the particular embodiments by those of skill in the art without departing from the scope of the disclosure, which is defined solely by the claims appended hereto.

What is claimed is:

1. A radiation detector comprising:
a substrate layer of detector material;
a set of readout electronics deposited and integrated on one side of the substrate layer; and
a contact layer deposited on a side of the substrate layer opposite the set of readout electronics.

2. The radiation detector of claim 1 wherein the set of readout electronics are a thin film transistor (TFT), a Schottky diode or a metal-semiconductor-insulator (MIS) diode.

3. The radiation detector of claim 1 wherein the substrate layer is a silicon substrate layer.

4. The radiation detector of claim 3 further comprising:
a semiconductor layer located between the silicon substrate layer and the contact layer.

5. The radiation detector of claim 3 wherein the silicon substrate layer is p-doped and the TFT is an n-type TFT.

6. The radiation detector of claim 3 wherein the silicon substrate layer is n-doped and the TFT is a p-type TFT.

7. The radiation detector of claim 3 wherein the silicon substrate layer is the semiconductor layer and the TFT is a metal-semiconductor TFT.

8. The radiation detector of claim 7 further comprising a Schottky barrier.

9. The radiation detector of claim 3 wherein the silicon substrate layer is the semiconductor and the TFT is a MIS capacitor.

10. The radiation detector of claim 1 wherein the detector material is one of silicon (Si), Indium Phosphide (InP), gallium arsenide (GaAs), cadmium telluride (CdTe), cadmium zinc telluride (CdZnTe or CZT) or the like.

11. The radiation detector of claim 1 wherein the contact layer is metal.

12. The radiation detector of claim 11 wherein the metal is aluminum.

13. The radiation detector of claim 2 further comprising elements for biasing the TFT and contact layer to produce an electric field within the substrate layer.

14. The radiation detector of claim 2 wherein the set of readout electronics is a top gate TFT.

15. A method of manufacturing a radiation detector comprising:
depositing a substrate layer of detector material;
depositing and integrating a set of readout electronics on one side of the substrate layer; and
depositing a contact layer on a side of the substrate layer opposite the set of readout electronics.

16. The method of claim 15 wherein depositing and integrating comprises:
depositing a thin film transistor (TFT).

17. The method of claim 15 further comprising:
depositing a semiconductor layer on the side of the substrate layer opposite the set of readout electronics before depositing the contact layer.

18. The method of claim 15 further comprising:
biasing the set of readout electronics and the contact layer to produce an electric field within the substrate layer.

19. The method of claim 16 wherein an n-type TFT is deposited if the substrate layer is p-doped.

20. The method of claim 16 wherein a p-type TFT is deposited if the substrate layer is n-doped.

21. The radiation detector of claim 2 wherein the semiconductor layer is used to form a Schottky barrier.

22. The method of claim 16 wherein depositing the semiconductor layer comprises depositing a Schottky barrier layer.

23. The radiation detector of claim 1 wherein the detector is for use in infrared optical imaging, visible optical imaging, ultraviolet optical imaging, X-ray imaging or gamma ray imaging.
